(19) United States
(12) Patent Application Publication
(10) Pub. No.: US 2007/0029580 A1
(43) Pub. Date: Feb. 8, 2007

(54) IMAGE-PROCESSING UNIT

(76) Inventors: Tsuan-Lun Lung, Hsinchu City (TW); Chih-Hung Cheng, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,528

(22) Filed: Aug. 8, 2005

(51) Int. Cl. H01L 27/148

(52) U.S. Cl. 257/233

(57) ABSTRACT

An image-processing unit for an image sensor is provided. The image-processing unit comprises a plurality of photodiodes arranged inside the image sensor. The photodiodes have different sensing area according to its location. Typically, the sensing area of the photodiodes increases from the center toward the periphery. Therefore, the attenuation of sensitivity caused by a larger incident angle away from the central region can be compensated to enhance image quality.

### BACKGROUND OF THE INVENTION

1. Field of the Invention

The present invention relates to an image sensor. More particularly, the present invention relates to an image-processing unit for a Complementary Metal-Oxide Semiconductor (CMOS) image sensor.

2. Description of the Related Art

CMOS image sensor is one type of opto-electronic conversion device capable of scanning an image pattern and converting the captured light signals into digital signals that can be identified, processed and stored by a computer. Because a CMOS image sensor utilizes an integrative opto-electronic module to sense the brightness/darkness of the image, compared with a charged-couple device (CCD) deploying complicated optical image-forming principles, the CMOS image sensor is simpler to design, easier to assemble and cheaper to produce and can be shaped into very lightweight, slim and compact product. Thus, CMOS image sensor has been applied to various products including, for example, scanners, digital camera and video camera.

The CMOS image sensor uses a pixel unit comprising an array of photodiodes to capture images. In general, the sensitivity of each pixel unit indicates the strength of conversion for converting the light signals projecting on the photodiodes into electrical signals. If the sensitivity of the photodiodes with respect to light is reduced, the accuracy and degree of saturation of the captured image may be directly affected.

It should be noted that a conventional contact image sensor has a pixel unit comprising a matrix of identical photodiodes or lines of identical photodiodes, all of which have the same size. However, the photodiodes located in the periphery or two side areas have a larger incident angle relative to the photodiodes located near the central area. Due to the larger incident angle, the photodiodes lying on one side or close to the peripheral areas have a lower sensitivity. Such attenuation of sensitivity toward the periphery will directly affect the captured image quality and lead to an image having a brighter center and a darker periphery. Although the light signals in the peripheral areas can be enhanced through the application of light compensating techniques that use software or the focus effect of a micro-lens or through computing the effective area of the sensing areas according to the image size, their effectiveness is often quite limited.

### SUMMARY OF THE INVENTION

Accordingly, at least one objective of the present invention is to provide an image-processing unit for improving the sensitivity of photodiodes located in peripheral or side areas.

To achieve these and other advantages and in accordance with the purpose of the invention, as embodied and broadly described herein, the invention provides an image-processing unit for an image sensor. The image-processing unit comprises a plurality of photodiodes arranged inside the image sensor. The photodiodes have different sensing area according to its location. The sensing area of the photodiodes increases from the center toward the periphery.

According to the preferred embodiment of the present invention, the image sensor is a CMOS image sensor, for example.

According to the preferred embodiment of the present invention, the photodiodes is arranged to form a matrix or lines within the image sensor, for example.

According to the preferred embodiment of the present invention, the photodiodes are divided into a plurality of blocks from the central area outward, for example. Furthermore, the photodiodes within each block has same sensing area.

According to the preferred embodiment of the present invention, the horizontal width of the sensing area of the photodiodes in the same row increases from the central area toward two sides.

According to the preferred embodiment of the present invention, the vertical height of the sensing area of the photodiodes in the same column increases from the central area toward two sides.

According to the preferred embodiment of the present invention, the increase in sensing area of each photodiode is proportional to the sine of the angle of incident of light.

According to the preferred embodiment of the present invention, the increase in sensing area of each photodiode is proportional to the degree of attenuation of the sensitivity.

In the present invention, photodiodes having different sensing area ratios are used to compensate for any attenuation of sensitivity due to a larger angle of incident of light. Thus, the photodiodes close to the peripheral areas or two sides have larger sensing areas for increasing light sensitivity and minimize the effect of light attenuation in the peripheral areas.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a diagram of an image-processing unit according to one preferred embodiment of the present invention.

FIG. 2 is a diagram showing the disposition between the image-processing unit and the incident light according to the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

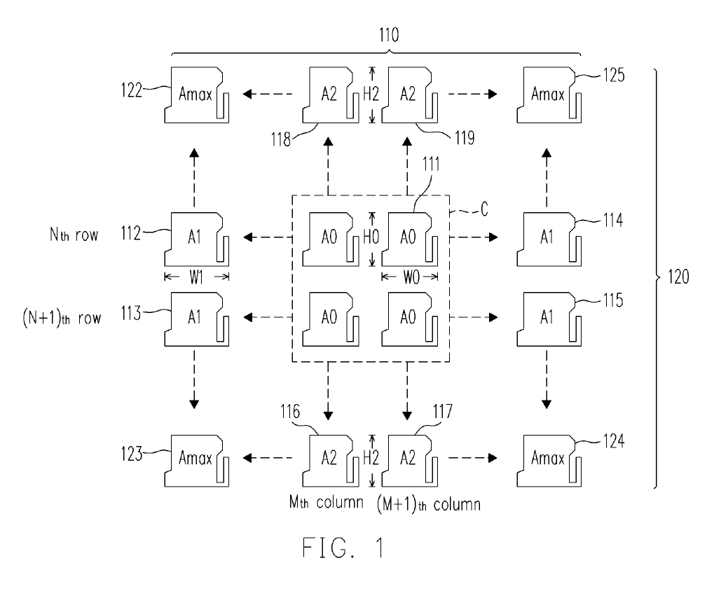

FIG. 1 is a diagram of an image-processing unit according to one preferred embodiment of the present invention. The method of driving the image-processing unit 100 and the principles for forming an image can be obtained by referring to prior techniques. The following description mainly deals with the arrangement of the sensing units and the dimensional variation of the sensing device inside the image-processing unit 100.

As shown in FIG. 1, the image-processing unit 100 mainly comprises a plurality of horizontally lined and vertically lined photodiodes 110 and 120. The photodiodes 110 and 120 can be arranged to form a pixel unit having a matrix structure through the layout design of semiconductor device so that the light signals incident upon the photodiodes 110, 120 can be captured and converted into readable electronic signals. One major difference of the present invention from a conventional technique is that the photodiodes 110 and 120 have different sensing area according to its location. In particular, the sensing area of the photodiodes 110, 120 increases from the central area toward the periphery.

As shown in FIG. 1, the photodiodes 111 in the central area C has the smallest sensing area A0. In other words, the photodiodes 111 have the smallest horizontal width W0 and the smallest vertical height H0. For the photodiodes 110, 120 outside the central area C, their sensing areas increase at a constant ratio along the horizontal axis or the vertical axis so that the photodiodes 112˜119 in the outermost peripheral areas have larger sensing areas A1, A2, relative to other inner photodiodes. Using the photodiodes 110 in the same row (the N^{th} row) as an example, the horizontal width W1 of the sensing area A1 results from a proportional increase of the horizontal width from the horizontal width W0 in the central area toward the two sides. Similarly, for the photodiodes 120 in the same column (the M^{th} column), the vertical height H1 of the sensing area A2 results from a proportional increase of the vertical height from the vertical height H0 in the central area.

As shown in FIG. 1, when the photodiodes 110, 120 are arranged to form a matrix and the horizontal width or the vertical height of the photodiodes 110, 112 in different columns and rows increases according to a constant ratio, the photodiodes 122˜125 at the four corner areas have the highest sensing area Aₘₐₓ. However, the present invention is not limited as such. In other words, aside from a matrix arrangement, the photodiodes can be arranged to form a plurality of lines. For example, when a number of photodiodes is aligned in a same row, the horizontal width of these photodiodes will increase from the central area C toward the two sides. Hence, the photodiodes in the two side areas have the largest sensing area Aₘₐₓ. Similarly, when a number of photodiodes is aligned in a same column, the vertical height of these photodiodes will increase from the central area C toward the two sides. Hence, the photodiodes in the two side areas have the largest sensing area Aₘₐₓ.

In the two above-mentioned embodiments, the photodiodes in ‘the central area’ may include a plurality of neighboring photodiodes all having same sensing areas while the remaining photodiodes outside the central area are divided into a plurality of blocks. Each block has a plurality of neighboring photodiodes all having same sensing area. However, it does not matter if the photodiodes are gathered into blocks, the dimension of these photodiodes may vary (increasing from the central area in an outward direction) to improve the attenuation of sensitivity near the peripheral areas.

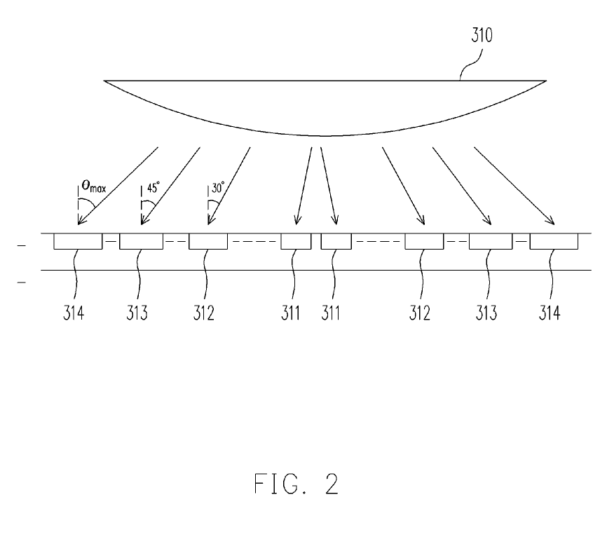

FIG. 2 is a diagram showing the disposition between the image-processing unit and the incident light according to the present invention. Using a CMOS image sensor as an example, light rays having different angle of incident are projected on the matrix or the lines of photodiodes 311˜314 after the light from an external image is refracted by a lens 310. The light signal having the smallest incident angle impinges upon the photodiodes 311 in the central area C. Since the incident angle increases towards the sides, the photodiodes 314 located in the peripheral or side areas have the largest angle of incident and correspondingly the largest sensitivity attenuation. It should be noted that the present invention utilizes the increase in sensing area in the peripheral or side areas to compensate for the lost in sensitivity in the photodiodes 314 due to a larger light incident angle.

According to theory of sine functions, the more angle of incident of a light, the more increase in sine value of the angle. Thus, the sensing area of the photodiodes 310 can be designed to increase at a constant ratio according to the sine value of the incident light. For example, if the sensing area of the photodiode 311 in the central area is A0, the sensing area of the photodiode 312 having a sine value of the incident light of sin 30° will increase from A0 to A0 (1+ sin 30°). When the sine value of the incident light increases to sin 45°, the sensing area of the photodiode 313 will increase from A0 to A0 (1+sin 45°). Accordingly, the sensing area of the two outermost photodiodes 314 will increase from A0 to A0 (1+sin θₘₐₓ).

In addition, the sensing area of the photodiode 310 may increase at a constant ratio according to the degree of attenuation of the sensitivity. For example, according to experimental data, when the sensitivity of the photodiodes 314 in the peripheral or side areas attenuates by 30%, the sensing area of the photodiodes 314 may increase from A0 to A0 (1+30%) to counteract peripheral attenuation. The aforementioned method of increasing the sensing area is used only as an example. In general, the actual design should be implemented with suitable adjustments.

Hence, it does not matter if peripheral sensitivity attenuation is caused by a large incident angle or other factors, the aforementioned method can be deployed to compensate for the attenuation and produce a high-quality image with more uniform brightness and color clarity.

In summary, the image-processing unit in the present invention is constructed using photodiodes having different sensing area. In particular, the sensing area of the photodiodes increases from the central area toward the two sides or from the central area toward the four peripheral areas to prevent a drop in the sensitivity through caused by too large an angle of incident of light. Hence, the problem of having a brighter central area and darker peripheral areas due to peripheral attenuation can be eliminated to increase the quality of captured images. In addition, the sensing area of the photodiodes may increase in constant proportion according to the sine value of the angle of incident light or the degree of attenuation of the sensitivity. Thus, high-quality images with more uniform brightness and color clarity can be produced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An image-processing unit for an image sensor, the image-processing unit comprising:
a plurality of photodiodes arranged inside the image sensor such that each photodiode has a sensing area whose size depends on its location, wherein the sensing area of the photodiodes increases away from a central area.

2. The image-processing unit of claim 1, wherein the image sensor includes a CMOS image sensor.

3. The image-processing unit of claim 1, wherein the photodiodes are disposed to form a matrix of photodiodes or lines of photodiodes inside the image sensor.

4. The image-processing unit of claim 1, wherein the photodiodes are divided into a plurality of blocks from the central area such that the blocks are adjacent to each other and the sensing area of the photodiodes within each block is same.

5. The image-processing unit of claim 1, wherein the horizontal width of the sensing area of all the photodiodes in the same row increases from the central area toward the two sides.

6. The image-processing unit of claim 1, wherein the vertical height of the sensing area of all the photodiodes in the same column increases from the central area toward the two sides.

7. The image-processing unit of claim 1, wherein the increase in sensing area of the photodiodes is proportional to the sine of the angle of an incident light projecting on the photodiodes.

8. The image-processing unit of claim 1, wherein the increase in sensing area of the photodiodes is proportional to the degree of attenuation of the sensitivity.

9. The image-processing unit of claim 1, further comprising a lens disposed over the photodiodes.
